(19) United States
(12) Patent Application Publication
(10) Pub. No.: US 2008/0197908 A1
(43) Pub. Date: Aug. 21, 2008

(54) Cascode Power Switch for use in a High-Frequency Power MESFET Buck Switching Power Supply

(75) Inventor: Richard K. Williams, Cupertino, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Santa Clara, CA (US)

(21) Appl. No.: 12/032,672

(22) Filed: Feb. 16, 2008

Related U.S. Application Data
(62) Division of application No. 11/307,202, filed on Jan. 26, 2006.

(51) Int. Cl. H03K 17/687

(52) U.S. Cl. 327/431; 327/434

(57) ABSTRACT

A cascode power switch for use in a MESFET based switching regulator includes a MOSFET in series with a normally-off MESFET. The cascode power switch is typically connected in between a power source and a node Vx. The node Vx is connected to an output node via an inductor and to ground via a Schottky diode or a second MESFET or both. A control circuit drives the MESFET (and the second MESFET) so that the inductor is alternately connected to the battery and to ground. The MOSFET is switched off during sleep or standby modes to minimize leakage current through the MESFET. The MOSFET is therefore switched at a low frequency compared to the MESFET and does not contribute significantly to switching losses in the converter.

### RELATED APPLICATIONS

This application is a divisional of pending U.S. patent application Ser. No. 11/307,202. The disclosures of the following related US patent applications are incorporated in this document by reference: Ser. No. 11/307,199, Ser. No. 11/307,200, Ser. No. 11/307,201, Ser. No. 11/307,203 and Ser. No. 11/307,204. This application is being filed concurrently with a second divisional entitled “High-Frequency Buck Converter that Includes a Cascode MESFET-MOSFET Power Switch.”

### BACKGROUND OF THE INVENTION

Voltage regulators are used commonly used in battery powered electronics to eliminate voltage variations resulting from the discharging of the battery and to supply power at the appropriate voltages to various microelectronic components such as digital ICs, semiconductor memory, display modules, hard disk drives, RF circuitry, microprocessors, digital signal processors and analog ICs. Since the DC input voltage must be stepped-up to a higher DC voltage, or stepped down to a lower DC voltage, such regulators are referred to as DC-to-DC converters.

Step-down converters are used whenever a battery's voltage is greater than the desired load voltage. Conversely, step-up converters, commonly referred to boost converters, are needed whenever a battery's voltage is lower than the voltage needed to power its load. Step-down converters include transistor current source methods called linear regulators, switched capacitor networks called charge pumps, or by circuit methods where current in an inductor is constantly switched in a controlled manner. Boost converters may be also be made from charge pump switched-capacitor networks or by switched inductor techniques. Switched inductor power voltage regulators and converters are commonly referred to as “switching converters”, “switch-mode power supplies”, or as “switching regulators”. Step-down switching converters using simple, rather than transformers, inductors are also be referred to as Buck converters.

### Trade-Offs in Switching Regulators

In either step-up or step-down DC to DC switching converters, one or more power switch elements are required to control the current and energy flow in the converter circuitry.

During operation these power devices act as power switches toggling on and off at high frequencies and with varying frequency or duration. During such operation, these power devices lose energy to self heating, both during periods of on-state conduction and during the act of switching. These switching and conduction losses adversely limit the power converter's efficiency, potentially create the need for cooling the power devices, and in battery powered applications shorten battery life.

Using today's conventional power transistors as power switching devices in switching regulator circuits, an unfavorable tradeoff exists between minimizing conduction losses and minimizing switching losses. State-of-the-art power devices used in switching power supplies today primarily comprise various forms of lateral and vertical metal-oxide-semiconductor silicon field-effect-transistors or “power MOSFETs”, including submicron MOSFETs scaled to large areas, vertical current flow double-diffused “DMOS” transistors, and vertical trench-gated versions of such DMOS transistors known as “trench FETs” or “trench DMOS” transistors.

Circuit and device operation at higher frequency, desirable to reduce the size of a converter's passive components (such as capacitors and inductors) and to improve transient regulation, involve compromises in choosing the right size power device. Larger lower resistance transistors exhibit less conduction losses, but manifest higher capacitance and increased switching losses. Smaller devices exhibit less switching related losses but have higher resistances and increased conduction losses. At higher switching frequencies this trade-off becomes increasingly more difficult to manage, especially for today's power MOSFET devices, where device and converter performance and efficiency must be compromised to achieve higher frequency operation.

Transistor operation at high frequency becomes especially problematic for converters operating at high input voltages (e.g. above 7V) and those operating at extremely low voltages (e.g. below 1.8 volts). In such applications, optimization of the power device involves even a stricter compromise between resistance and capacitive losses, offering narrower range of possible solutions.

### Conventional Prior-Art DC/DC Converters

FIG. 1 describes a prior art Buck-type DC/DC converter used to step-down and produce a lower-voltage regulated output (such as 2.7 volts) from a time varying DC input (such as a 3.6V lithium ion battery). In such switching regulators, the on-time of a power switch is constantly adjusted to regulate the output voltage of the converter despite variations in load current or battery voltage. In fixed frequency converters, the on-time is adjusted by varying, i.e. modulating, the power switch's pulse width. Such converters are referred to as pulse width modulation (PWM) control. PWM controllers are easily modified to operate at variable frequencies, or to switch between fixed and variable modes automatically during low-current load conditions.

In the prior-art embodiment of boost converter shown in circuit 1, the output of PWM control circuit 2 drives gate-buffer 3 which in turn drives the input of P-channel power MOSFET 4. PWM control 2 and Buffer 3 are powered directly from the battery voltage Vbatt. The drain of P-channel MOSFET 4, switched at a high-frequency (typically at 700 kHz or more) controls the average current through inductor 6. Because the inductor forces voltage Vx negative whenever current is interrupted in MOSFET switch 4, the drain of P-channel MOSFET 4 remains more negative than Vbatt, reverse biasing diode 5, so no diode current flows. Diode 5 is a drain-to-source antiparallel PN junction diode intrinsic to power MOSFET 4, and not an added circuit component. The drain of P-channel MOSFET 4 is also connected to ground through diode 7. Whenever current is interrupted in MOSFET 4 and the voltage at Vx drops below ground, Schottky diode 7 forward-biases and recirculates current through diode 7.

Feedback from the output of the converter is used to vary the pulse width produced of PWM control circuit 2 to hold the output voltage constant under varying conditions of battery voltage and load current. Capacitor 8 filters high frequency switching noise out of the converter.

Converter 1 suffers from several major deficiencies. The biggest problem with this converter design is that a large low-resistance power MOSFET does not make a good high frequency switch. Making the MOSFET large enough to exhibit low on-resistance requires a device with large capacitance which results in excessive switching losses associated with driving its gate at high frequencies. Using a smaller MOSFET may reduce switching losses but increases I²R conduction loss. The tradeoff between gate drive losses and conduction losses becomes more severe at higher frequencies, and becomes prohibitively lossy above a few Megahertz.

Gate drive loss driving a P-channel switch can be substantial, particularly at high frequencies. To achieve the lowest on-state resistance, gate buffer 3 must drive P-channel MOSFET 4 with the maximum possible gate drive without damaging the gate oxide of MOSFET 4. Typical MOSFETs fabricated in IC processes allow maximum gate to source potentials of 3.3V, 5.5V, or 13.2V. Discrete MOSFETs are typically rated at 12V or 20V. So long that the maximum battery voltage does not exceed the maximum gate rating of the P-channel MOSFET, buffer 3 normally drives the P-channel from rail-to-rail, i.e. switching between Vbatt and ground. The energy used to charge the power MOSFET's gate capacitance is thrown away, i.e. discharged to ground, during every switching cycle, and therefore contributes to the converter's overall power loss. Since gate buffer 3 is powered directly from the battery input, variations in the battery voltage during its discharge causes constant changes in the on-resistance, conduction loss, and gate drive loss contributions associated with driving the MOSFET, making optimization more difficult.

The gate drive loss is worse for P-channel MOSFETs than for N-channel transistors since P-channel devices have roughly twice the on-resistance and capacitance as comparably sized N-channel devices. Using an N-channel MOSFET as a high-side, i.e. battery connected, device is problematic since driving the gate of such a device requires a voltage greater than the input voltage of the converter. Typically, this requires floating gate drive circuits that include one or more capacitors to provide the required voltage. Not only does this add complexity, but since the capacitors in these circuits take time to charge during each switching cycle, the size and capacitance of the high side transistor drive is limited to some maximum switching frequency.

The limitations of conventional silicon MOSFETs are illustrated in the electrical characteristics of FIG. 2 shown for a variety of on and off conditions. FIG. 2A illustrates the “family of curves” for an N-channel MOSFET showing the drain current I_{D} versus drain-to-source voltage V_{DS} where curves 12, through 15 illustrate curves of increasing gate voltage V_{GS}, for example in one-volt increments. Curve 12 represents the special condition of zero-volt gate drive, i.e. V_{GS}=0, and is often referred to by the nomenclature I_{DSS}. If a device conducts substantially no current under this bias condition, that is if I_{DSS}is small, the device is referred to as an enhancement mode, or “normally-off” type MOSFET. Normally off devices are preferred as switches in most power electronic applications, since their default condition is “off”.

The “turn-on” or threshold voltage Vₜₒ of two different MOSFETs is illustrated in FIG. 2B in the graph of I_{D} versus V_{GS}. MOSFET “A” shown by curve 16 has a higher threshold voltage than MOSFET “B” shown by curve 17. Typical threshold voltages for a type A device range from 1V to 2V, while type B have voltages of 0.8V and no lower than 0.6V.

Provided the threshold voltage of either device remains above approximately 0.6V, the avalanche breakdown curve 18 of both type devices have an off-state characteristic at V_{GS}=0 as shown in the linear-scale graph of FIG. 2C, where the graph is plotted in the single-digit microampere range.

The log-scale graph of FIG. 2D, however, reveals the lower threshold device B (curve 20) has a different behavior and on a comparative basis substantially greater off-state leakage than the higher threshold device A (curve 19), despite the fact that they may exhibit the same avalanche breakdown voltage. This leakage increases with decreasing threshold and increasing temperature, especially for thresholds below 0.6V, making the device unattractive as a normally-off power switch. Beneficially, however, the linear-region on-state resistance, or “on-resistance” for the lower threshold device B is lower than that of the higher threshold device A as shown in the hyperbolic on-resistance curves 22 and 21 respectively in FIG. 2E. The benefit is asymptotically minimized at increasing gate biases.

FIGS. 2F and 2G illustrate a fundamental tradeoff in on-state and off-state performance of a MOSFET parametrically as a function of threshold Vₜₒ. In FIG. 2F, on-resistance R_{DS} is shown as a function of threshold voltage Vₜₒ. Curve 23 illustrates the on-resistance of low-threshold device B is less than high-threshold device A, biased under the same gate drive condition, e.g. at V_{GS}=3.6V. At a lower gate bias shown by curve 24, e.g. at V_{GS}<2V, not only is the on-resistance increased categorically, but the sensitivity of on-resistance to threshold voltage is greatly increased, where device A has a significantly higher resistance than device B.

FIG. 2G illustrates the threshold dependence of the off-state leakage I_{DSS}. Curve 25 illustrates the dependence on leakage as a function of threshold voltage, where device B exhibits higher leakages than device A. Lowering a MOSFET's threshold voltage lead to a rapid increase in leakage current. Clearly a compromise exists between the low leakage of device A and the low on-resistance of device B. To minimize on-resistance simply by lowering threshold in the extreme renders any silicon MOSFET too leaky to use. Conversely, raising a MOSFET's threshold, e.g. by changing its construction, increases the device's on-resistance.

In addition to the tradeoff between leakage and on-resistance, a power MOSFET also exhibits a trade-off between its on-resistance and its switching losses. In devices operating at voltages less than one hundred volts and especially below thirty volts, switching losses are dominated by those losses associated with driving its gate on and off, i.e. charging and discharging its input capacitance. Such gate drive related switching losses are often referred to as “drive losses”. To this point, FIG. 3 illustrates a graph of MOSFET's gate drive voltage V_{GS} versus its on-resistance R_{DS} and on gate charge Q_{G}. Gate charge is a measure of the electrical charge necessary to charge a MOSFET's electrical input capacitance to that specific gate voltage condition.

Gate charge is used in preference to predicting a transistor's behavior by capacitance since a MOSFET's capacitances are nonlinear and voltage dependent, especially over the large-signal voltage range used in switching applications. As an integral of voltage and capacitance, gate charge increases in proportion gate bias V_{GS} as illustrated by curve 27. The rapid increase in gate charge at a bias condition of (Vₜₒ+ΔV) shown by region 28 in the gate charge curve is due to charging of the MOSFET's gate to drain overlap capacitance when the device switches from off to on.

In contrast to gate charge increasing in proportion gate bias V_{GS}, curve 26 illustrates on-resistance decreases with increasing gate bias. The product of gate charge and on-resistance, or Q_{G}·R_{DS}, as shown by curve 28 in FIG. 3 exhibits a minimum value at some gate bias above the MOSFET's threshold. This minimum exemplifies the intrinsic trade-off between conduction losses (arising from on resistance) and switching losses (arising from driving the transistor's gate) in a power MOSFET. Overdriving the gate to higher voltages decreases on-resistance but increases gate charge and gate drive losses. Inadequate gate drive leads to large increases in on-resistance, especially below or near threshold voltage.

Minimizing the Q_{G}·R_{DS} product a silicon MOSFET is difficult since changes intended to improve gate charge tend to adversely impact on-resistance. For example, doubling a transistor's size and gate width will (at best) halve its on-resistance but double its gate charge. The resulting Q_{G}·R_{DS} product is therefore unchanged, or in some cases even increased.

Designing a transistor to exhibit low on-resistance by reducing threshold voltage requires the use of thinner gate oxides. Thinning the gate oxide however, not only limits the maximum safe gate voltage, but increases gate charge. The resulting device remains un-optimized for high frequency power switching applications.

### Using Other Semiconductor Materials

The compromises involving gate charge, on resistance, breakdown, and off leakage in power MOSFETs previously described represent physical phenomena fundamentally related to the semiconductor material itself, in this case silicon. If we consider these limitations as an intrinsic property of the silicon material itself, then an alternative approach to realize a low-voltage high frequency power transistor switch may employ non-silicon semiconductor materials. While silicon carbide, semiconducting diamond, and indium phosphide may hold some promise to meet this need in the future, the only material sufficiently mature for practical application today is gallium arsenide, or GaAs.

GaAs has to date however only been commercialized for use in high-frequency and small signal applications like radio frequency amplifiers and RF switches. Historically, its limited use is due to a variety of issues including high cost, low yield, and numerous device issues including fragility, and its inability to fabricate a MOSFET or any other insulated gate active device. While cost and yield issues have diminished (somewhat) over the last decade, the device issues persist.

The greatest limitation in device fabrication results from its inability to form a thermal oxide. Oxidation of gallium arsenide leads to porous leaky and poor quality dielectrics and unwanted segregation and redistribution of the crystal's binary elements and stoichiometry. Deposited oxides, nitrides, and oxy-nitrides exhibit too many surface states to be used as a MOSFET gate dielectric. Without any available dielectric, isolation between GaAs devices is also problematic, and has thwarted many commercial efforts to achieve higher levels of integration prevalent in silicon devices and silicon integrated circuits.

These issues aside, one approach successfully used to make a prior art GaAs field-effect transistor without the need for a gate oxide or high temperature processing is the metal-epitaxial-semiconductor field-effect transistor, or MESFET as shown in FIG. 4A. In cross section 30, the transistor is fabricated in a GaAs mesa 32 formed atop semi-insulating GaAs substrate 31. The device is isolated by an etched mesa to separate each device from adjacent devices. Rather than implanting and annealing dopant to form N+ regions 34, the N+ layer is grown as part of the epitaxial process used to form N− epitaxial layer 33.

The device uses a Schottky metal gate 36 formed in a shallow etched trench 35 and contact by metal electrode 38. The gate trench is etched sufficiently deep to transect N+ layer 34 into two sections, one acting as the transistor's source contacted by source metal 39, the other acting as its drain and contacted by metal 37. The Schottky metal is typically a refractory metal, typically titanium, tungsten, cobalt, or platinum chosen for the electrical properties of the junction it forms with N− GaAs layer 33. The Schottky metal is spaced from the side of the trench to prevent contact to the N+ region 34 which would result in high gate leakage. The interconnect metal is chosen to make an ohmic contact with both N+ layer 34 and the Schottky gate material 36. Contact to the gate Schottky metal 36 is achieved by metal interconnect 35 making sure the interconnect metal does not directly touch epi layer 33.

Operation of device 30 is unipolar, where the depletion region formed by the Schottky barrier between gate material 36 and epi layer 33 is influenced by the gate potential of electrode 38, and modulates the electron flow between source 37 and drain 39. The gate 36 transects the entire mesa 32 to prevent any N+ surface leakage currents. All current must therefore flow beneath trench 35, modulated by the depletion region of the Schottky junction. Since no current is intentionally injected into the gate, the device operates as a field effect transistor, as depicted in FIG. 4B as the same schematic element 40 used for a JFET, except that the gate is Schottky and not a diffused junction. No substantial current flows through the semi-insulating substrate 31 which may include an added P-N junction or sandwich layer of varying materials superimposed between epi layer 33 and substrate 31 to further suppress substrate leakage

FIG. 4C illustrates the family of curves for a conventional MESFET which we shall here denote as a “type B” device. Curve 40 illustrates the drain current that results from operating the devices with its gate shorted to its source, i.e. V_{GS0}=0. The non-zero I_{DSS} current indicates that the device is normally on, otherwise known in MOSFET vernacular as “depletion mode”. Curve 41, 42, and 43 at increasing positive gate biases of V_{GS1}, V_{GS2}, and V_{GS3} respectively illustrates that the drain current is increased by slightly forward biasing the gate electrode. The gate can only be forward biased to the voltage at which the Schottky junction becomes forward biased and the depletion region shrinks to its minimum extent. Beyond V_{GS3}, the gate-to-source voltage becomes clamped at the Schottky's forward voltage, typically 0.8 to 0.9V. The compressed spacing between the family-of-curves, e.g. between curves 42 and 43, illustrate that beyond some bias additional forward biasing of the gate produces diminishing benefits in device conductivity. Excessive forwarding biasing of the Schottky junction at high current densities may also permanently damage the device.

FIG. 4C also illustrates that the drain current can be suppressed below IDSS by further reverse biasing the Schottky junction, i.e. by applying a negative gate-to-source bias as depicted by curves 44, 45, and 46 operated at gate potentials −V_{GS4}, −V_{GS5}, −V_{GS6} respectively. The reduced current results from the increased pinching of the drain current under the gate by the reverse biased depletion region. The compressed spacing between the family of curves, e.g. between curves 45 and 46 illustrates that further increases in reverse gate bias result in diminishing benefits in suppressing drain current. Note that the maximum extent of the depletion region may be unable to pinch-off the drain current totally, in which case the device cannot be fully turned off. Such a device, where the minimum drain leakage I_{Dmin} is substantially above zero, does not make a useful power switch. An alternate description of a depletion mode transistor is one where I_{DSS}>I_{Dmin}, i.e. where the zero biased gate is far above the minimum achievable leakage current.

### SUMMARY

The present invention relates to buck converters that are preferably, but not necessarily based on the type of MESFET described in the US patent application entitled “Rugged MESFET for Power Application.” This type of MESFET, referred to in this document as a “Type A” MESFET is a normally off device with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). These characteristics make Type A MESFETs particularly suitable as power switches in Boost converters, Buck converters, Buck-boost converters, flyback converters, forward converters, full-bridge converters, and more.

One type of MESFET-based buck converter includes an N-channel MESFET connected to control the flow of current from a battery (or other power source) to a node Vx. A Schottky diode is connected between the node Vx and ground and is oriented so that no current flows from the node Vx to ground. An inductor is connected between the node Vx and an output node. An output capacitor is connected between the output node and ground. The N-channel MESFET is driven by a specialized gate buffer that provides unique drive properties matched to the MESFET. The gate buffer is powered using a bootstrap circuit that provides a voltage that exceeds the battery voltage. Details of the gate buffer and bootstrap circuit are more fully described in the copending U.S. patent application: “High Frequency Power MESFET Gate Drive Circuits.” A Zener diode is optionally connected in parallel with the N-channel MESFET to protect the MESFET from over-voltage conditions. The Zener diode must be in close proximity to the MESFET, and should ideally be in the same package.

During operation, the MESFET is enabled and disabled under control of a PWM circuit, which may operate in constant frequency pulse-width-modulation (PWM) mode or may operate in a variable frequency or pulse frequency mode (PFM) (or in any mixture of PWM and PFM). When the MESFET is enabled, current flows through the inductor to the output node. When the MESFET is disabled, current continues to flow from the inductor to the output node as the magnetic field of the inductor collapses. The output capacitor filters ripple in the voltage at the output node.

A second type of MESFET-based buck converter replaces the Schottky diode in the converter just described with a second N-channel MESFET driven by a gate buffer. The gate buffer for the second N-channel MESFET is a specialized circuit with unique drive properties matched to the MESFET. Suitable gate buffer circuits are described in the copending U.S. patent application: “High Frequency Power MESFET Gate Drive Circuits.” A break-before-make (BBM) circuit is added to the PWM circuit to prevent both the condition where both MESFETS are enabled simultaneously. A Schottky diode is connected in parallel with the MESFET of the second N-channel MESFET. The Schottky diode provides a conduction path between ground and the inductor whenever both MESFETs are off at the same time (e.g., during dead time enforced by the BBM circuit). As a variation of this design, the second N-channel MESFET may be replaced with an N or P-channel MOSFET.

Both of the buck converters described are capable of operation at high switching frequencies. At switching frequencies of 1 MHz, the inductor L can be selected to be approximately 5 μH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

### Low-Leakage Cascode Power MESFET-MOSFET Switch

To improve the performance of MESFET based-buck converters, it is possible to replace the main (i.e., low-side) N-channel MESFET with a series connection of an N-channel MESFET and some other switch, such an N-channel MOSFET. The MOSFET has much lower off-state leakage current and higher off-state resistance than the MESFET but is more costly in power consumption to switch at high frequencies. This tradeoff in capabilities can be used advantageously by switching the MOSFET off to prevent leakage during standby or sleep-mode operation or during any other long duration of inactivity and holding the MOSFET on whenever the MESFET is switching. Several possible permutations of this design are possible. For the first, a cascode switch is established with a drain node connected to an N-channel MESFET. The MESFET is connected to an N-channel MOSFET that is connected to the source node of the cascode. A second permutation reverses the ordering of the MESFET and MOSFET so that the MOSFET is connected to the cascode drain and the MESFET is connected to the cascode source. Alternately, either of these configurations may be produced using P-channel MOSFETs.

The drive characteristics of MESFETs and MOSFETs are different. As a result, it will generally be the case that switching converters will include separate gate buffers for the MOSFET and MESFET whenever a cascode switch is used. The signal used to control the MOSFET's gate is also different than the one controlling the MESFET's gate, both in frequency and in their purpose.

### Protected Cascode MESFET-MOSFET Switch

To prevent unwanted avalanche breakdown and hot-carrier generation the maximum voltage present over a MESFET must never be allowed to approach the avalanche point, even in during a momentary voltage transient. For this reason, it is desirable to place a Zener diode in parallel with the MESFET in each of the cascode switches just described. Alternately, the cascode switches may be constructed with the Zener diode in parallel with the combination of MESFET and MOSFET.

### Cascode MESFET-MOSFET Buck Converters

The cascode switches just described may be used to produce highly efficient buck converters. A representative implementation of a converter of this type includes a cascode switch connected to control the flow of current from a battery (or other power source) to a node Vx. A Schottky diode is connected between the node Vx and ground and is oriented so that no current flows from the node Vx to ground. An inductor is connected between the node Vx and an output node. An output capacitor is connected between the output node and ground. The N-channel MESFET of the cascode switch is driven by a specialized gate buffer that provides unique drive properties matched to the MESFET. The gate buffer is powered using a bootstrap circuit that provides a voltage that exceeds the battery voltage. Details of the gate buffer and bootstrap circuit are more fully described in the copending U.S. patent application: “High Frequency Power MESFET Gate Drive Circuits.” A Zener diode is optionally connected in parallel with the N-channel MESFET to protect the MESFET from over-voltage conditions. The Zener diode must be in close proximity to the MESFET, and should ideally be in the same package. Importantly, the cascode switch may be any of the permutations described previously, including both N and P-channel types.

During operation, the MESFET is enabled and disabled under control of a PWM circuit, which may operate in constant frequency pulse-width-modulation (PWM) mode or may operate in a variable frequency or pulse frequency mode (PFM) (or in any mixture of PWM and PFM). When the MESFET is enabled, current flows through the inductor to the output node. When the MESFET is disabled, current continues to flow from the inductor to the output node as the magnetic field of the inductor collapses. The output capacitor filters ripple in the voltage at the output node.

A second type of MESFET-based buck converter replaces the Schottky diode in the converter just described with a second N-channel MESFET driven by a gate buffer. The gate buffer for the second N-channel MESFET is a specialized circuit with unique drive properties matched to the MESFET. Suitable gate buffer circuits are described in the copending U.S. patent application: “High Frequency Power MESFET Gate Drive Circuits.” A break-before-make (BBM) circuit is added to the PWM circuit to prevent both the condition where both MESFETs are enabled simultaneously. A Schottky diode is connected in parallel with the MESFET of the second N-channel MESFET. The Schottky diode provides a conduction path between ground and the inductor whenever both MESFETS are off at the same time (e.g., during dead time enforced by the BBM circuit). As a variation of this design, the second N-channel MESFET may be replaced with an N or P-channel MOSFET.

Additional variations on the MESFET based switching regulators described above are possible. If every switching regulator is assumed to include a low-side switch and a high-side switch the following combinations are possible:

(1) low-side switch: Schottky diode, high-side switch: N-channel MESFET.

(2) low-side switch: Schottky diode, high-side switch: MESFET cascode switch.

(3) low-side switch: N-channel MESFET, high-side switch: Schottky diode.

(4) low-side switch: N-channel MESFET, high-side switch: N-channel MESFET.

(5) low-side switch: N-channel MESFET, high-side switch: MESFET cascode switch.

(6) low-side switch: N-channel MESFET, high-side switch: MOSFET.

(7) low-side switch: MOSFET, high-side switch: N-channel MESFET.

(8) low-side switch: MOSFET, high-side switch: MESFET cascode switch.

(9) low-side switch: MESFET cascode switch, high-side switch: Schottky diode.

(10) low-side switch: MESFET cascode switch, high-side switch: MOSFET.

(11) low-side switch: MESFET cascode switch, high-side switch: N-channel MESFET.

(12) low-side switch: MESFET cascode switch, high-side switch: MESFET cascode switch.

(13) Of these various circuit topologies, combinations (1) and (2) are uniquely suitable for Buck converters while (3) and (9) are dedicated to boost converters.

While the remaining combinations may be used for Buck, boost, or the combination of Buck and boost (i.e. Buck boost) converters, those employing MOSFETs as a high speed switch, namely topologies (6), (7), (8), and (10) will suffer efficiency degradation at higher switching frequencies and are therefore contraindicated. In the application of topologies (3) to (12) in realizing a Buck converter, the high-side switch functions as the switch controlling the energy input into the converter, while the low-side switch acts a synchronous rectifier recirculating inductor current whenever the high-side switch is off.

### DESCRIPTION OF FIGURES

FIG. 1 Buck switching converter using power MOSFET switch (Prior Art).

FIG. 2 Power MOSFET electrical characteristics (A) family of drain curves (B) gate dependence of drain current for high and low Vt devices (C) avalanche breakdown characteristics (D) drain leakage (log scale) for high and low Vt devices (E) gate dependence of on-resistance for high and low Vt devices (F) threshold dependence of on-resistance (G) threshold dependence of drain leakage.

FIG. 3 V_{GS} dependence of power MOSFET gate charge and on-resistance.

FIG. 4 GaAs MESFET cross section and electrical characteristics (A) prior-art cross section (B) symbol (C) “type B” prior-art family-of- curves (D) hypothetical “type A” family-of-curves (E) gate characteristics (F) gate dependence of on resistance for two device types.

FIG. 5 MESFET DC/DC boost converters (A) Buck converter (B) synchronous Buck converter.

FIG. 6 Various MESFET-MOSFET cascode switch characteristics (A) N-channel series circuit (B) off-state leakage characteristics (C) cascode and MESFET on-state resistance (D) inverted N-channel series circuit (E) P-channel MOSFET version (F) inverted P-channel MOSFET version.

FIG. 7 Avalanche and leakage mechanisms in normally-off (enhancement mode) MESFET.

FIG. 8 Zener clamped MESFET switches (A) quadrant I current-voltage characteristics (B) equivalent clamped MESFET circuit (C) N-channel series circuit with MESFET clamp (D) N-channel series circuit with antiparallel clamp (E) P-channel MOSFET series circuit with MESFET clamp (F) P-channel MOSFET series circuit with N-channel MESFET and antiparallel clamp.

FIG. 9 Cascode MOSFET-MESFET Buck converter with high-side P-channel Switch.

FIG. 10 Alternative cascode MOSFET-MESFET Buck converter topologies (A) battery connected MESFET with P-channel enable (B) floating N-channel enable

FIG. 11 Cascode MESFET-MOSFET synchronous Buck converter with battery-connected P-channel MOSFET enable.

FIG. 12 Cascode MESFET-MOSFET synchronous Buck converter with battery connected MESFET.

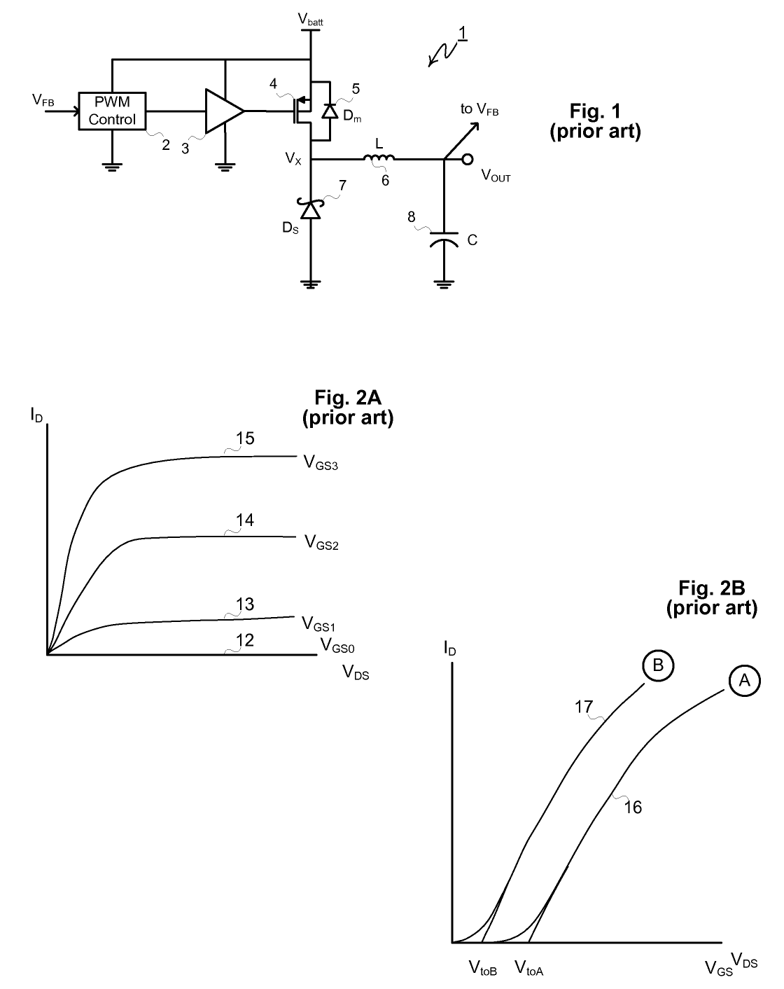

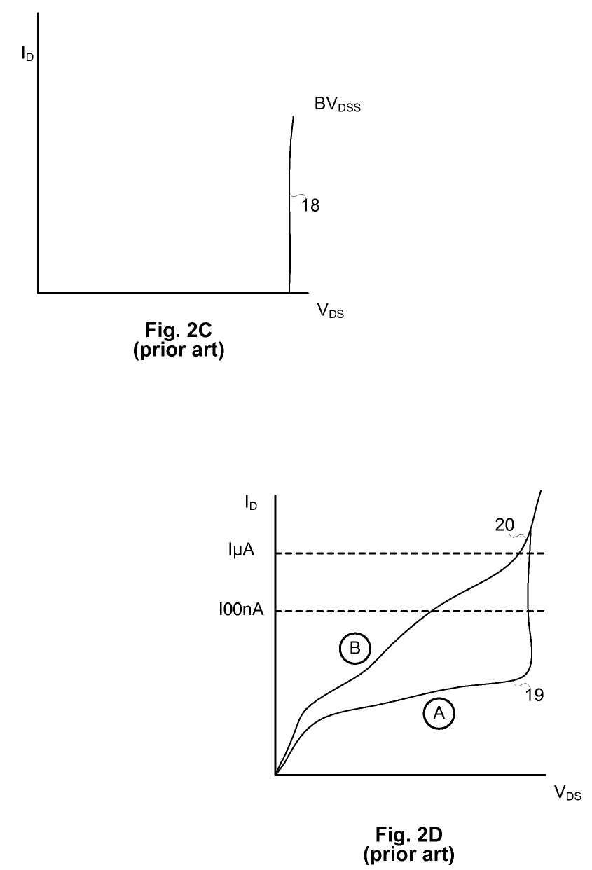

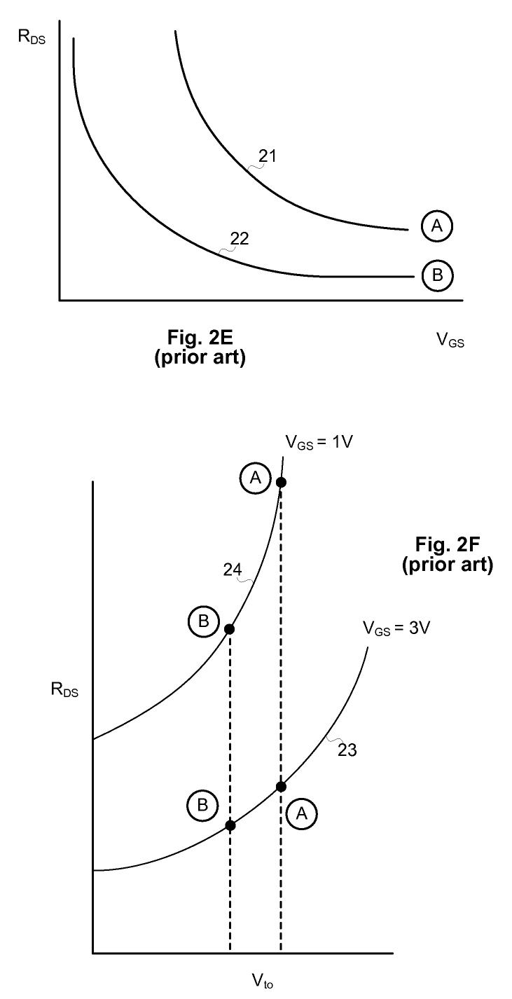

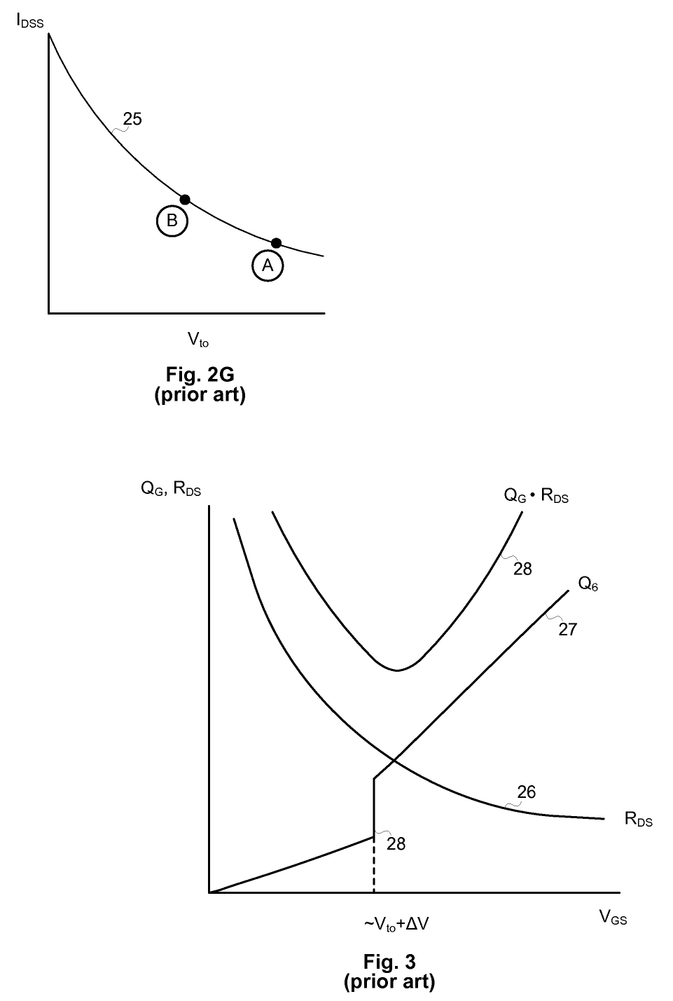

### DESCRIPTION OF INVENTION

The present invention includes inventive matter regarding the use of a proposed power MESFET in switching power supplies. The proposed power MESFET is referred to in this document as a “type A” device. Before describing the use of the “type A” device in switching power supplies, a short description of the “type A” device is presented. A more complete description of the “type A” device and its applications is included the related patent applications previously identified.

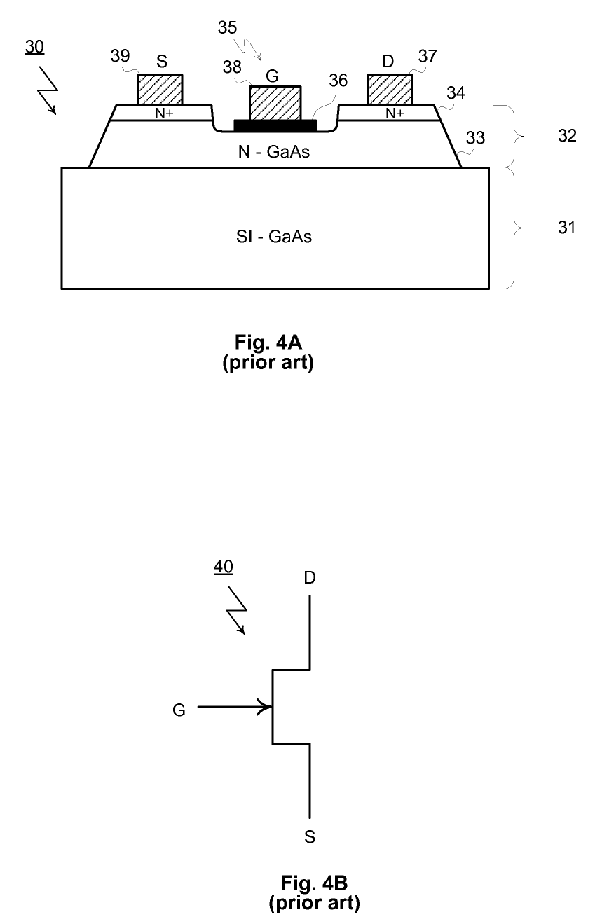

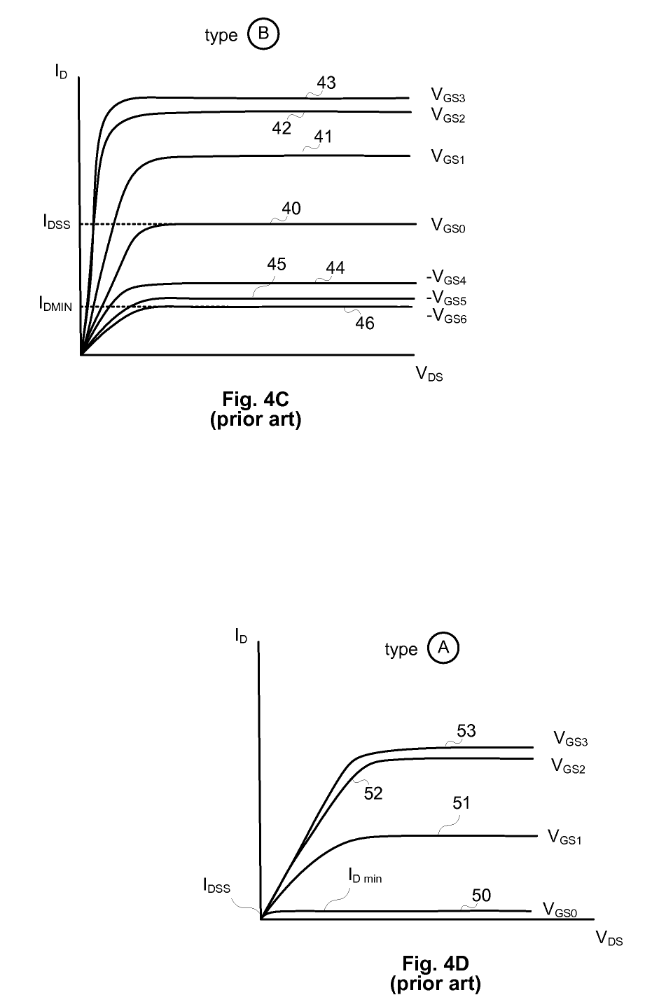

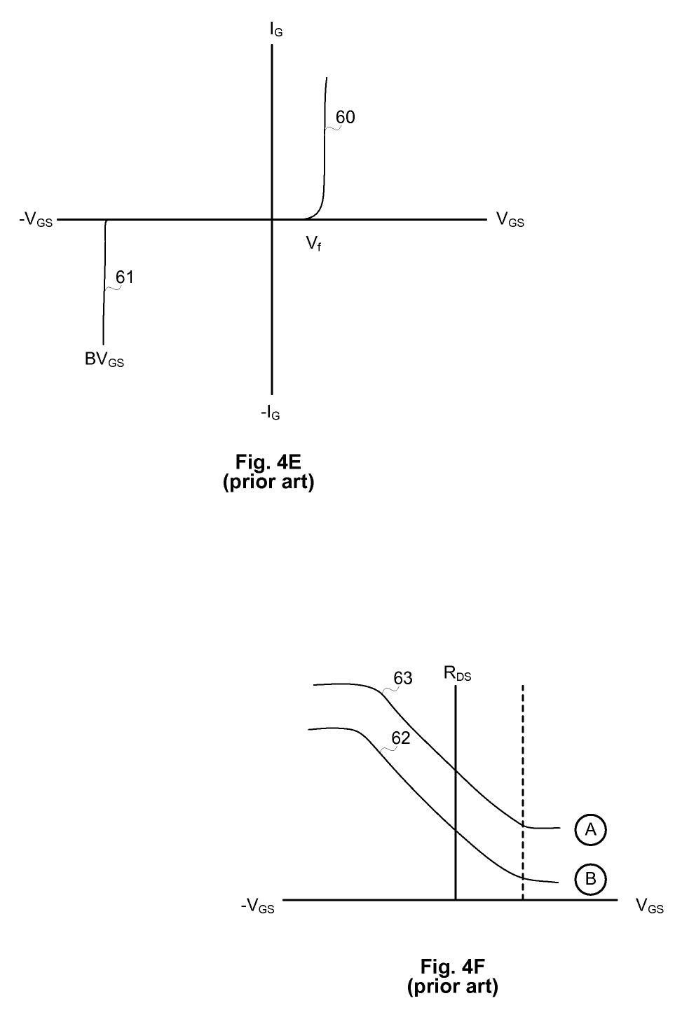

FIG. 4D illustrates how the previously described “type B” depletion-mode device would need to be adjusted to make a power switch with useful characteristics (i.e., the “type A” device). Similar to an enhancement mode MOSFET, the proposed “type A” MESFET needs to exhibit a near zero value of I_{DSS} current, i.e. the current I_{Dmin} shown as line 50 should be as low as reasonably possible at V_{GS0}=0, i.e. where I_{DSS}≈I_{Dmin}. Biasing the Schottky gate with positive potentials of V_{GS1}, V_{GS2}, and V_{GS3} results in increasing currents 51, 52, and 53, respectively, clamped to some maximum value by conduction current in the Schottky gate. There is no need to apply negative gate bias to such a device.

The range in gate voltages V_{GS} that a MESFET may be operated is, unlike an insulated gate device or MOSFET, bounded in two extremes as shown in FIG. 4E. In the direction of forward bias as shown by curve 60 the maximum gate bias is V_{F}, the forward bias voltage of the Schottky at the onset of conduction. In the reverse direction, line 61 represents the Schottky avalanche voltage. Extreme bias conditions, whether forward or reverse biased can damage the fragile MESFET. Moreover, driving the MESFET gate into forward conduction leads to DC power losses from gate conduction, adversely impacting the efficiency of power converters using the device.

FIG. 4F illustrates a theoretical comparison of the linear region on-resistance of the two MESFET types as a function of V_{GS}. The less leaky proposed “type A” device is expected to exhibit a higher resistance than the normally on “type B” device.

Ideally then, a power switch suitable for very high-frequency DC/DC conversion a normally off device with low on-state resistance, low off-state drain leakage, minimal gate leakage, rugged (non-fragile) gate characteristics, robust avalanche characteristics, low turn-on voltage, low input capacitance (i.e. low gate charge), and low internal gate resistance (for fast signal propagation across the device). Such a power device will then be capable of operating at high frequencies with low drive requirements, low switching losses, and low on-state conduction losses. Implementing such a power switch using a MESFET such as the GaAs MESFET previously described, a MESFET must be substantially modified in its fabrication and its use, and may require changes in its fabrication process, mask layout, drive circuitry, packaging, and its need for protection against various potentially damaging electrical conditions.

### Power MESFETs Buck Converter

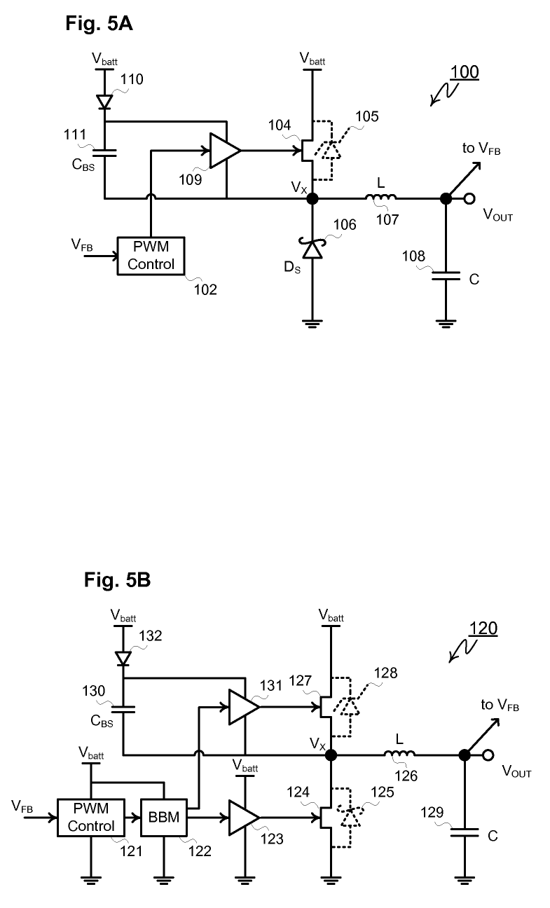

FIG. 5A illustrates an inventive Buck converter using a MESFET as the power switch. In this example power MESFET 104 is switched at a high frequency by gate buffer 109 powered directly from the battery. The on-time, duty factor and switching frequency of power MESFET 104 is controlled by PWM circuit 102, where said PWM circuit may operate in constant frequency pulse-width-modulation (PWM) mode or may operate in a variable frequency or pulse frequency mode (PFM). PWM circuit 102 draws its power from the converter's battery input.

Voltage reduction and regulation is achieved by controlling the current in inductor 107 through the switching action of MESFET 104. Whenever current in MESFET 104 is interrupted, the voltage Vx immediately drops below ground, and Schottky diode 106 conducts.

Zener diode 105 is optionally available to provide protection against over-voltage conditions damaging the MESFET switch. In contrast to prior art MOSFET based converters, the need for a Zener diode 105 in limiting the maximum drain voltage Vx across MESFET 104 is unique to the MESFET based Buck converter. Using a MOSFET (like in circuit 1 of FIG. 1), noise spikes across the switching device can be absorbed by the MOSFET's intrinsic P-N drain-to-source junction. The MESFET, however, being unipolar in construction, has no intrinsic P-N junction to act as a voltage clamp, giving rise to the device's deficiency in avalanche ruggedness. In such cases it is important to clamp the maximum drain to source voltage to avoid device damage.

Theoretically, since the voltage Vx in a Buck converter is limited to the range between Vbatt and a diode drop below ground (i.e., to −V_{F}), the maximum drain-to-source voltage across MESFET 104 is already limited and Zener diode 105 should not be needed. But because of stray inductance in series with the source and drain of the MESFET switch, the voltage transients across the device can greatly exceed the supply voltage, albeit for short durations, and potentially damage the device, especially at higher frequencies where the MESFET switch offers performance advantages.

At switching frequencies of 1 MHz, inductor L can be selected to be approximately 5 pH. At 10 to 40 MHz operation however, the inductance required is 500 to 50 nH. Such small values of inductance are sufficiently small to be integrated into semiconductor packages, offering users a reduction is size, lower board assembly costs, and greater ease of use.

Gate drive buffer block 109 drives the Schottky gate input of high-side MESFET 104, powered by bootstrap capacitor 111, which is charged through diode 110 whenever Vx is near ground or below Vbatt. Gate buffer 109 may be inverting or non-inverting since there is no risk of shoot through current in the combination of MESFET 104 and reverse biased Schottky 106. Note also, that gate buffer 109 and the source of MESFET 104 share a common connection, which is not ground, but instead is connected to inductor 107 and the cathode of diode 106. Time permitting, bootstrap capacitor 111 is charged to a voltage of (Vbatt−V_{D}) where V_{D} is the forward drop on diode 110 during conduction. When MESFET 104 is turned on, voltage Vx rises near Vbatt. Since the voltage on capacitor 111 cannot change instantly, the capacitor voltage “floats” on top of Vx as it rises, i.e. is bootstrapped with the output, maintaining gate drive on the gate of MESFET 104 even to a voltage greater than the battery input. The maximum gate voltage relative to ground is therefore (2·Vbatt−V_{D}) but the maximum V_{GS} of the MESFET remains (Vbatt−V_{D}) due to the floating source voltage of the high-side device.

For driving the gate of a power MESFET, the buffer supply voltage (Vbatt−V_{D}) is too large. Gate buffer 109 is therefore not just a conventional CMOS gate buffer, but must provide unique drive properties matched to MESFET 104. Specifically, in the event that gate buffer 109 drives the gate of MESFET 104 at too high of current or too much voltage, the resulting high gate current can lead to excessive power loss, localized heating, oscillations, and even device damage. Gate buffer 109 must rapidly drive MESFET gate 104 to the proper on-state bias condition without underdriving or overdriving the device during switching transitions.

Without the bootstrap supply however, MESFET 104 would be supplied with inadequate gate drive, i.e. where the current capability of buffer 109 is too low to charge the input capacitance of MESFET in the time required for high frequency operation, or that the output voltage of buffer 109 is too low to fully turn-on MESFET 104 into a low-resistance fully conductive operating state, leading to excessive conduction losses.

FIG. 5B illustrates an inventive synchronous Buck converter using a MESFET as the converter's main power switch and another MESFET as a synchronous rectifier. In this example power MESFET 127 is switched at a high frequency by gate buffer 131 powered through a bootstrap floating supply and gate drive comprising gate buffer 131, bootstrap capacitor 130, and bootstrap diode 132. The on-time, duty factor and switching frequency of power MESFET 127 is controlled by PWM circuit 121, where said PWM circuit may operate in constant frequency pulse-width-modulation (PWM) mode or may operate in a variable frequency or pulse frequency mode (PFM). PWM circuit 121 is powered directly the battery or converter input.

The output of PWM circuit 121 drives break-before-make (BBM) circuit 122 which in turn drives floating gate buffer 131 and high-side MESFET 127, as well as low-side gate buffer 123 and synchronous rectifier MESFET 124. Break before make (BBM) circuit 122 provides deadtime protection to prevent both the main switch (comprising power MESFET 127), and the synchronous regulator (comprising MESFET 124) from conducting simultaneously and shorting out the battery input of the converter.

To reduce switching noise and output ripple, the output of the converter is filtered by output filter capacitor 129. Zener diode 128 is optionally available to provide protection against over-voltage conditions damaging the MESFET switch 127. Above switching frequencies of 1 MHz, inductor L can be made small similar to circuit 100 of FIG. 5A.

Step-down voltage regulation is achieved by the switching action of MESFET 127 to control the current in inductor 126. Whenever the current in high-side MESFET 127 is interrupted, the voltage Vx rapidly drops below ground forward biasing Schottky rectifier 125. After the break-before-make interval N-channel power MESFET 124 also conducts shunting the current from Schottky 125 through the MESFET's channel and reducing overall voltage drop and power dissipation. Since conduction in MESFET occurs synchronous to conduction in Schottky 125, then MESFET 125 may be considered as a synchronous rectifier.

Gate drive buffer block 131 drives the gate input of high-side MESFET 127 and gate buffer 123 drives the gate of low-side MESFET 124. Gate buffers 123 and 131 are not just conventional CMOS gate buffers, but must provide unique drive properties matched to their respective MESFETs. Failure to properly drive either MESFET can lead to noisy circuit operation and increased conduction losses if either MESFET is supplied with inadequate gate drive, i.e. where the current capability of the gate buffer is too low to charge the input capacitance of the MESFET in the time required for high frequency operation, or that the output voltage of the gate buffer is too low to fully turn-on the MESFET into a low-resistance fully conductive operating state. Conversely, in the event that either gate buffer drives the gate of a MESFET at too high of current or too much voltage, the resulting high gate current can lead to excessive power loss, localized heating, oscillations, and even device damage.

Operation of a DC-to-DC switching converter as shown in circuits 100 and 120 using a normally-off power MESFET switch are capable of high-efficiency operation at multi-MHz frequencies because of the device's low on-resistance, low gate charge, and low turn-on (threshold) voltage. The performance benefit is especially beneficial lithium ion applications where conventional MOSFET's are not fully conductive at gate bias conditions as low as 3V, the lowest operating voltage of a lithium ion battery.

### Low-Leakage Cascode Power MESFET-MOSFET Switch

In battery powered applications, it is often necessary to place the converter into standby or sleep mode where it may remain for days or even weeks without being operated. In such situations even the slightest off-state leakage, leakages in the range of a few microamperes can shorten standby time by continuously “bleeding” the battery dry through a low current discharge. Any current which discharges the battery faster than the natural electro-chemical discharge rate of the battery represents a theoretical loss in performance and an opportunity for improving battery life.

This type of leakage problem is manifest in converter 100 of FIG. 5A since there is no means to prevent leakage from the battery to ground through MESFET 104, conducting through inductor 107 and to ground through the converter's load. In its off state, MESFET 104 still leaks drain current in the microampere range, and slowly discharges the battery powering its input.

This type of leakage problem is also manifest in synchronous Buck converter circuit 120 since the combination of high-side MESFET 127 and low-side MESFET 124 form a direct leakage “shunt” across the converter's input—the battery terminals. In their off state, MESFETs 127 and 124 both leak drain current in the microampere range, and slowly discharges the battery powering its input.

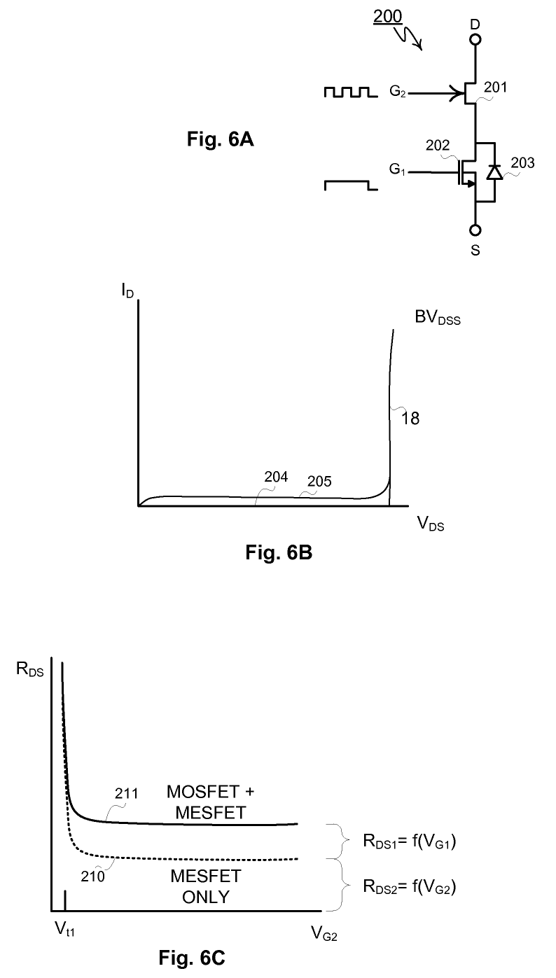

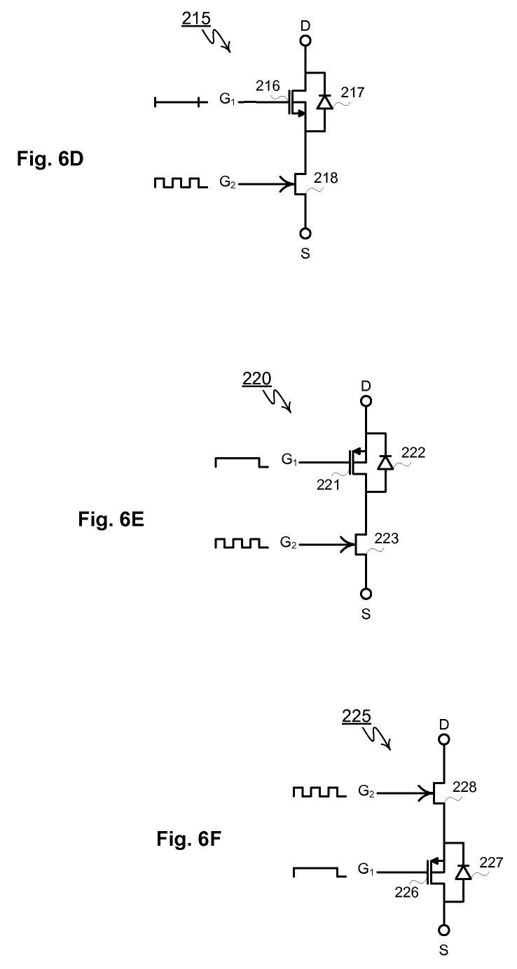

FIG. 6A illustrates a method to eliminate this unwanted leakage through a cascode configured switch 200 comprising MESFET 201 and series connected MOSFET 203 further containing drain-source intrinsic diode 203. MESFET 201 can, for example, be made of GaAs while MOSFET 202 can be made of silicon. Since silicon and GaAs wafer fabrication are generally incompatible, the two die can be assembled together in a multi-die or stacked-die package.

FIG. 6B illustrates compares the leakage property of the MESFET and MOSFET cascode combination. Whenever MOSFET 202 is off, the leakage property of the cascode device 200 is very low, approaching zero on linear scale graph as shown by curve 204. Whenever MOSFET 202 is turned on in preparation for converter operation, the switch leakage shown by curve 205 is that of the MESFET 201. To apply this switch in a DC-to-DC boost converter, MESFET 201 is switched at a high frequency whenever MOSFET 202 is held on. MOSFET 202 is only turned off after longer periods of inactivity, for example whenever the converter doesn't operate for over one or even several seconds. Since MOSFET 202 is not being switched at a high frequency, its does not substantially contribute to the overall capacitance, gate charge, or switching losses of the cascode device.

It should be noted that the BV_{DSS} of the combined cascode device. Ideally this device should have a blocking voltage equal to the sum of the breakdown voltages of MESFET 201 and MOSFET 202, i.e. the breakdown of intrinsic diode 203. Since the two series devices form a capacitor divider, however, it is possible during rapid transients to force the MESFET 201 into temporary transient breakdown, which may damage the device. Without adding some extra voltage clamp, it is prudent to choose MOSFET 202 to have a breakdown higher than that of MESFET 201. In converter applications, MOSFET 202 (with its intrinsic drain-to-body diode 203) should have a breakdown greater than the maximum voltage expected across the switch. In a Buck converter the MOSFET's avalanche voltage need only exceed the battery input voltage (plus some guardband for noise).

Curve 210 in FIG. 6C illustrates the on-state resistance R_{DS2} of MESFET 201 as a function of gate drive V_{G2}. Curve 211 illustrates the total resistance (R_{DS2}+R_{DS1}) of the cascode combination of MOSFET 202 and MESFET 201 as a function of MESFET gate drive V_{GS2} assuming a constant gate voltage V_{GS1} is used to bias MOSFET 202. Depending on the size and active gate width of both devices, the total resistance of the cascode switch may be increased or decreased as needed.

Ideally MESFET 203 should be made only slightly bigger than required to meet its required on-resistance and to minimize its gate charge and capacitance since it is the only device switching at the high frequency. In many applications, a usefully low value of on-resistance is in the range of typically several hundred milliohms or less, occupying an area of under 1 mm².

If a higher-current must be delivered, MESFET 203 can be oversized to decrease its resistance with minimal adverse impact to its input capacitance, gate charge, and gate-drive-related switching losses. The drain leakage does however increase in proportion to the MESFET's channel width. The use of large gate width low resistance MESFETs in a converter makes the need for a MOSFET cascode switch all the more critical to suppress leakage when the converter is not operating.

The size of MOSFET 202 can be increased to reduce its on-resistance without adversely impacting off-state leakage, e.g. with resistances in the range of 0.5 ohms to as low as several milliohms. The MOSFET on-resistance can be adjusted without adversely impacting gate drive losses in the switching converter since the MOSFET is turned-on and turned-off infrequently, at a frequency substantially less than the clock rate driving the gate of MESFET 201. The MOSFET may be manufactured using a lateral or a vertical process technology, including trench gated vertical power MOSFETS.

The gate voltage V_{GS1} driving MOSFET 202 is supplied by a separate gate buffer since the gate drive requirements of the MESFET and MOSFET differ in voltage and frequency. Accordingly, the devices should not be driven with the same gate buffer, but instead have separate gate buffers ideally powered from differing voltages. In the event that only a single power source is available, MOSFET 102 must be increased in size to adequately conduct to start the boost converter operating, and then thereafter MOSFET conduction losses can be minimized by powering its gate from the converter's output rather than from the battery directly.

The gates of the two devices should be driven independently since the voltage needed to fully enhance MOSFET 202 is much higher than the gate drive needed for MESFET 201, typically two to five times greater. Specifically, since the turn-on voltage of MESFET 102 is very low, generally well under one volt and typically around 0.5V, it may be powered by either the output or the battery directly. In a boost converter, powering the MESFET from the battery directly offers the benefit of lower gate drive losses since excess gate drive only leads to increased power losses and unwanted MESFET gate current. The gate drive for MOSFET 202 should be greater, ideally over 3V and even 5V as needed. In a preferred embodiment, operation in a DC/DC converter switches MESFET 201 on and off at a high frequency while switching of MOSFET 202 occurs at a low frequency, essentially to serve as a circuit enable (shut-off switch) to minimize leakage in long durations of off-time.

FIG. 6D illustrates an alternative cascode connection 215 where N-channel MOSFET 216 has its source connected to MESFET 218 rather than drain connected in cascode 200 as shown in FIG. 6A. Both cascode configurations are able to suppress series off-state leakage by shutting off the MOSFET. The avalanche voltage of this device, like that of cascode 200 is theoretically the sum of the MESFET and MOSFET avalanche voltages, but during a voltage transient, will distribute the drain voltage in proportion to the capacitance ratio of the devices. Depending on the duration, the more fragile MESFET may be damaged if excess voltage drives it deep into avalanche breakdown. The MOSFET's intrinsic diode 217 therefore does not guarantee protection of MESFET 218 under every circumstance, but has affords a greater degree of protection if MOSFET 216 is chosen to have an avalanche voltage greater than the maximum expected voltage in the application.

An alternative implementation of a cascode MOSFET-MESFET switch circuit is shown in FIG. 6E where P-channel MOSFET 221 (with its intrinsic diode 222) is used in place of an N-channel to control the leakage of the N-channel power MESFET 223. Such a configuration is useful when the cascode switch is utilized as a high-side switch (i.e., connected to the positive input voltage of a converter) or as a floating device (i.e., not connected to ground) since P-channel MOSFET 221 can easily be turned on by biasing its gate G₁ negative with respect to its source. The N-channel MESFET still requires a floating gate drive circuit since its proper operation requires its gate G₂ is biased to a voltage more positive than its source.

An inverted version of the high-side cascode switch is shown in FIG. 6F. In this version cascode switch 225 comprises series connected P-channel MOSFET 226 (and its intrinsic diode 227) and N-channel MESFET 228 except that the source of P-channel MOSFET 226 is connected to MESFET 228 rather than its drain. Like cascode 220, inverted cascode switch 225 is generally easier to drive in applications where the cascode switch is used as a high-side or floating device. In Buck converters, the P-channel cascode device is preferred as a high side switch while in boost converters it is best employed as the synchronous rectifier device.

### Protected Cascode MESFET-MOSFET Switch

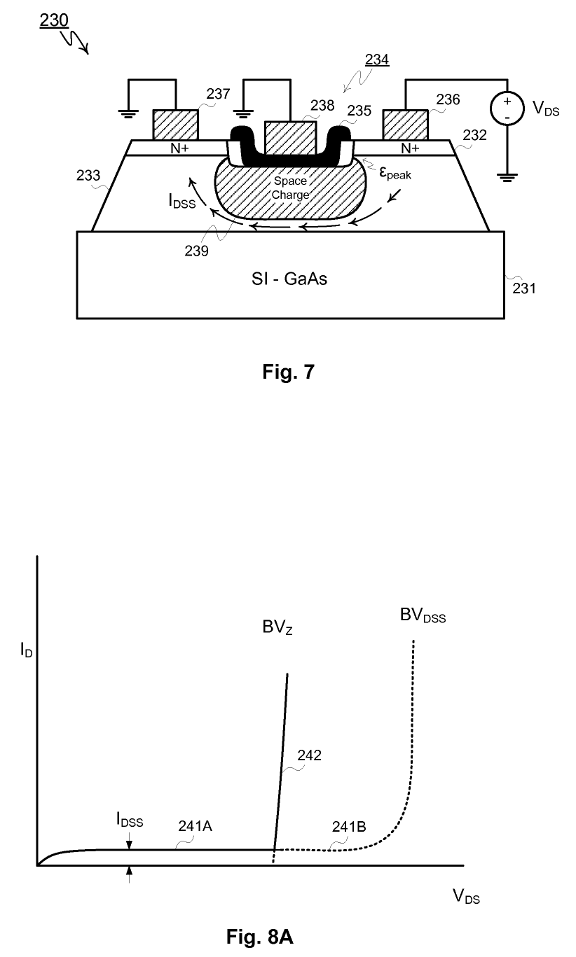

FIG. 7 illustrates the leakage and avalanche current conduction mechanisms in the cross sectional view of normally off MESFET 230 fabricated to exhibit normally-off behavior with a positive threshold voltage and a low off-state drain-leakage characteristic. The mesa structure comprising an N-GaAs layer 233 located atop a semi-insulating (SI) GaAs substrate 231 where the top of said GaAs substrate may comprise a sandwich of P-N junctions or alternating materials to further suppress substrate leakage. Included in epi layer 233 is trench gate 234 with Schottky gate metal 235 along with source and drain N+ regions 232.

In the off condition, MESFET 230 with grounded gate and source terminals 238 and 237 has its drain 236 biased at a potential V_{DS} forming depletion region 239 and pinching off any drain-to-source current except for leakage I_{DSS}. The peak electric field is located somewhere along the semiconductor surface in the vicinity of the trench and the edge of the Schottky gate. This location exhibits electric field crowding, impact ionization, and at a sufficiently high electric fields, potentially damaging avalanche breakdown. This avalanche can also be considered as a two-dimensional breakdown of the gate-to-drain Schottky diode. To prevent unwanted avalanche breakdown and hot-carrier generation the maximum voltage present across the device must never be allowed to approach the avalanche point, even during a momentary voltage transient.

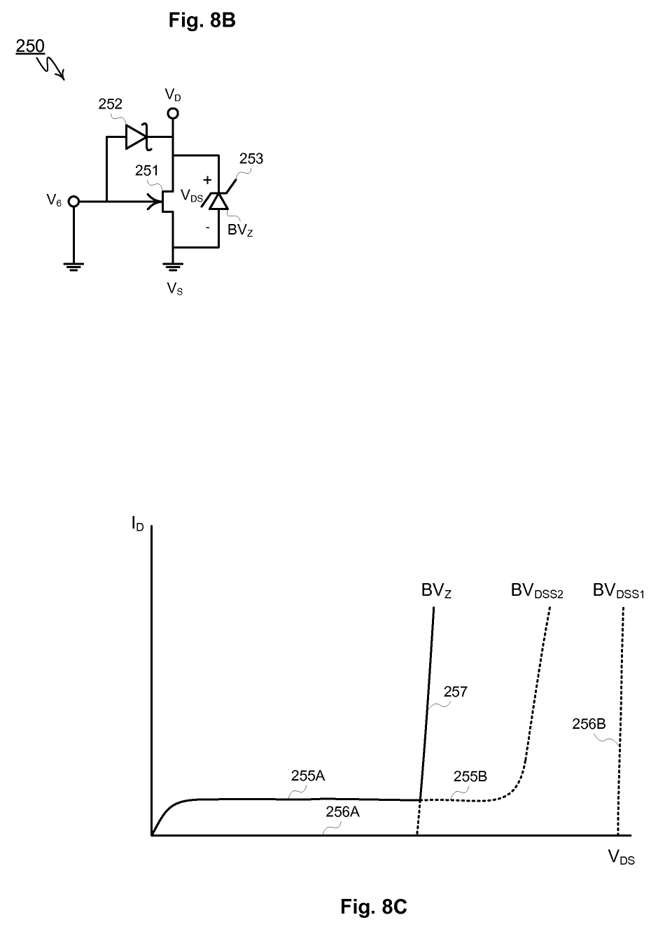

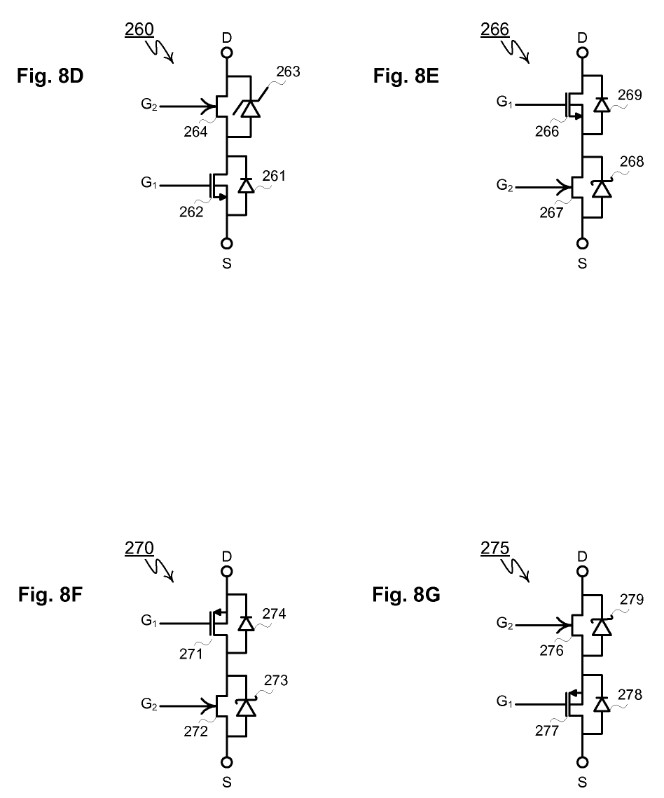

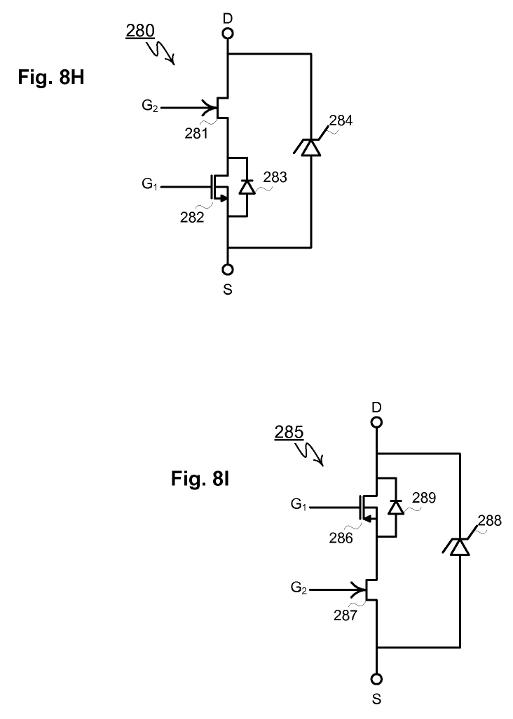

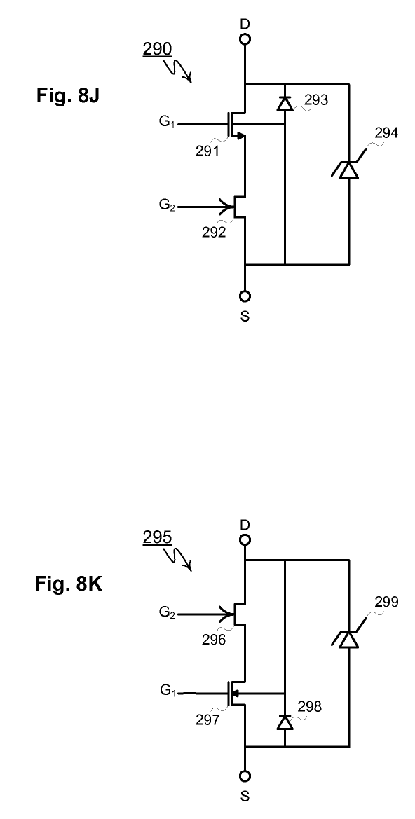

FIG. 8A illustrates the current voltage characteristics of a MESFET having I_{DSS} leakage 241A and avalanche breakdown 241B. To prevent potentially damaging avalanche in the device, the MESFET must be clamped by a Zener diode with a breakdown 242 of magnitude BV_{Z} sufficiently lower than the MESFET's breakdown voltage 241B to prevent any substantial impact ionization in the MESFET. This voltage guardband should be at least 2V and more ideally at least 5V. The combined characteristic of the clamped MESFET comprises the solid line portion of curves 241A and 242

The equivalent schematic of the voltage clamped MESFET in FIG. 8B is represented biased in its off-state by circuit 250 including MESFET 251, intrinsic gate-to-drain Schottky diode 252, and Zener clamp 253. In device 250, no mechanism to suppress leakage is represented other than the MESFET's intrinsic characteristics. In order to protect MESFET circuit 250, the clamp voltage BV_{Z} of Zener diode 253 is chosen to be less than the onset of avalanche or impact ionization in MESFET 251.

FIG. 8C illustrates the current-voltage characteristics of the voltage-clamped cascode MESFET-MOSFET switch shown schematically as circuit 260 in FIG. 8D. Specifically, curves 255A and 255B respectively illustrate the leakage and breakdown characteristics of MESFET 264 in the absence of Zener diode 263 whenever MOSFET 262 is on. Conversely curves 256A and 256B respectively illustrate the leakage and breakdown characteristics of MOSFET 262 whenever MESFET 264 is on. Breakdown 255B, having a voltage BV_{DSS2}, represents the avalanche voltage of MESFET 264 (a potentially damaging condition) while voltage BV_{DSS1} represents the drain-to-source breakdown of MOSFET 262 with its robust intrinsic drain-to-body diode 261. The addition of Zener clamp diode 263 limits the maximum voltage of the cascode switch across MESFET 264 to the voltage BV_{Z} as shown by curve 257 whenever MOSFET 262 is on, as shown by the solid portion of curves 255A and 257.

Zener breakdown voltage is chosen to be less than the avalanche voltage or the onset of impact ionization in MESFET 264, i.e. where BV_{Z}<BV_{DSS2}, in order to protect the less robust MESFET from potential damage. In the case that both MESFET 264 and MOSFET 262 are biased into an “off” condition, the theoretical breakdown voltage of the device is (BV_{DSS1}+BV_{Z}), but because of the capacitive divider effect during transients either device may be driven momentarily into avalanche. So long as Zener 263 is present, MESFET 264 remains protected.

A variant of Zener clamped cascode switch 260 is the clamped cascode switch 265 of FIG. 8E comprising floating N-channel MOSFET 266 with intrinsic diode 269 with its source connected to MESFET 267 and Zener clamp diode 268. Operation of cascode switch 266 is similar to circuit 260 except that the MESFET and MOSFET series connection has been reversed. Zener clamped cascode switch implementations can be used for any circuit switch topology including high side switches, low-side switches, and floating switching, but are especially convenient in low-side switch applications like the main switch in a boost converter.

Another variant of this approach useful for high side switches and floating devices includes the clamped cascode switch 270 of FIG. 8F comprising high-side P-channel MOSFET 271 with intrinsic diode 274 with its drain connected to MESFET 272 and Zener clamp diode 273. Similarly, a variant of this approach include the clamped cascode switch 275 of FIG. 8G comprising floating P-channel MOSFET 277 with intrinsic diode 278 with its drain connected to MESFET 276 and Zener clamp diode 279.

Another version of the clamped cascode MESFET-MOSFET switch of this invention is represented in the circuits shown in FIG. 8H and FIG. 8I. In circuit 280 Zener-clamp 284 is in parallel to the series combination of N-channel MESFET 281 and N-channel MOSFET 282. The maximum voltage of the cascode switch is then limited to the breakdown of Zener diode 284, i.e. BV_{Z}, regardless of whether MOSFET 282 is on or off. The value of BVZ should be chosen to be less than the breakdown of MESFET 281 and less than the breakdown of the MOSFET's intrinsic diode 283, mathematically as BV_{Z}<BV_{DSS2} and BV_{Z}<BV_{DSS1} respectively. Such a Zener clamped cascode switch has the same breakdown voltage independent of which switch is on or off. Strictly speaking, the criteria that the Zener breaks down at a voltage less than the MOSFET's avalanche voltage is not required so long as the MOSFET is relatively avalanche rugged and that the criteria BV_{Z}<BV_{DSS2} is strictly observed.

Similarly, in high-side or floating cascode switch circuit 285 shown in FIG. 8I, Zener-clamp 288 is in parallel to the series combination of N-channel MESFET 287 and P-channel MOSFET 286. The maximum voltage of the cascode switch is then limited to the breakdown of Zener diode 288, i.e. BV_{Z}, regardless of whether MOSFET 286 is on or off. The value of BV_{Z} should be chosen to be less than the breakdown of MESFET 287 and optionally less than the breakdown of the MOSFET's intrinsic diode 289, mathematically as BV_{Z}<BV_{DSS2} and BV_{Z}<BV_{DSS1} respectively. In other words, whether the MESFET is connected above or below the MOSFET has no impact on the breakdown characteristics of this approach.

In the prior examples, the source-to-body of the MOSFET is shorted, resulting in an anti-parallel source-to-drain diode (structurally comprising the MOSFET's gate-to-drain diode). Another method to implement a Zener clamped cascode switch is shown in FIG. 8J and in FIG. 8K which does not employ a MOSFET source-to-body short. Specifically, in circuit 290 N-channel MOSFET 291 has its source connected to the drain of N-channel MESFET 292 while the MOSFET's body is connected to the MESFET's source. The drain-to-body diode intrinsic to MOSFET 291 then acts as a diode clamp in parallel with the series combination of MOSFET 291 and MESFET 292. Provided the breakdown of diode 293 is lower than the breakdown of MESFET 292, i.e. BV_{DSS1}<BV_{DSS2}, the MESFET is protected. If the MOSFET's breakdown is not lower than the MESFET, then Zener diode 294 may be added, provided that the Zener voltage is lower than the MESFET's breakdown voltage BV_{Z}<BV_{DSS2}.

Similarly in circuit 295 P-channel MOSFET 297 has its source connected to the drain of N-channel MESFET 296 while the MOSFET's body is connected to the MESFET's source. The drain-to-body diode intrinsic to MOSFET 298 then acts as a diode clamp in parallel with the series combination of MOSFET 297 and MESFET 296. Provided the breakdown of diode 298 is lower than the breakdown of MESFET 296, i.e. BV_{DSS1}<BV_{DSS2}, the MESFET is protected. If the MOSFET's breakdown is not lower than the MESFET, then Zener diode 299 may be added, provided that the Zener voltage is lower than the MESFET's breakdown voltage BV_{Z}<BV_{DSS2}.

### Cascode MESFET-MOSFET Buck Converters

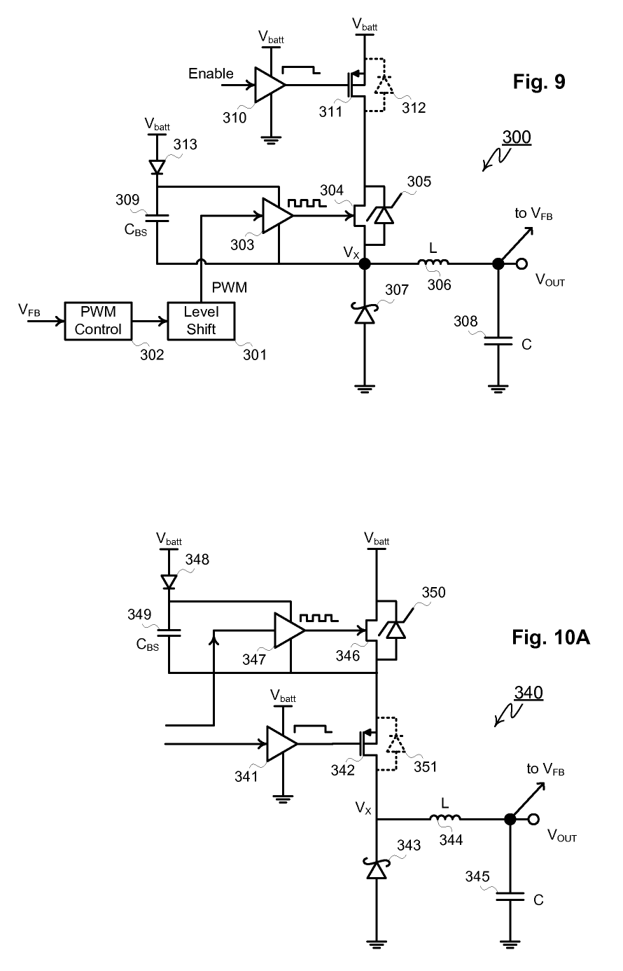

FIG. 9 illustrates an improved Buck switching converter and voltage regulator 300 using the aforementioned MESFET-MOSFET cascode switch, combined with Schottky rectifier 307. In this circuit, MESFET 304 is switched at a high frequency to control the average current through inductor 306 and through feedback of the output voltage and pulse-width modulation controls the output voltage across filter capacitor 308. No synchronous rectifier is employed in this circuit—Schottky rectifier 307 recirculates inductor 306 current whenever MESFET switch 304 is off clamping the voltage to a few hundred millivolts below ground. P-channel MOSFET 311, in series with MESFET 304, is enabled and conducting during converter operation and otherwise disabled during times when the converter is not operating. It is therefore switched at a much lower frequency than MESFET 312.

As described in reference to FIG. 6A, the problem of MESFET 304 is that it may leak current in the off condition, thereby discharging the battery. To avoid this problem, converter 300 has added an N-channel MOSFET 311 to shut off the leakage. An inverter 310 drives the gate through MOSFET 311. Diode 312 is part of the transistor intrinsic to MOSFET 311. Since this device is not being switched at a high frequency, the MOSFET can be sized for low on-resistance and low power dissipation without adversely affecting switching losses.

In this converter, the output of PWM control circuit 302 drives gate-buffer 303 which in turn drives the input of the power device, in this case N-channel MESFET 304. PWM circuit 302 is powered from the battery voltage. Gate drive buffer is not simply a CMOS inverter, but must limit the maximum gate voltage and current driving MESFET 304. Unlike a conventional MOSFET, a power MESFET has a Schottky gate input. Failure to limit the MESFET's gate drive will increase drive losses, lower converter efficiency, and in the extreme may damage the device. MESFET gate drive methods are the subject of U.S. patent application “High Frequency Power MESFET Gate Drive Circuits” included herein by reference.

Gate drive 303 is powered by a boot strap circuit comprising bootstrap capacitor 309 and bootstrap diode 313. Bootstrap capacitor 309 charged to a voltage (Vbatt−V_{D}) whenever Vx is near ground, i.e. whenever floating MESFET 304 is not conducting (V_{D} is the forward voltage across diode 313 whenever capacitor 309 is being charged).

When MESFET 304 is conducting (provided MOSFET 311 is enabled) Vx rises to near Vbatt and the potential across buffer 303 and bootstrap capacitor 309 rises to a voltage (relative to ground) above Vbatt, specifically (2·Vbatt−V_{D}). Since the source of MESFET 304 shares a common connection to gate buffer 303 and bootstrap capacitor 309, the entire gate buffer circuit “floats” with Vx. Level shift circuit 301 is illustrated to show that the ground-referenced logic level output of PWM circuit 302 must be re-referenced to the floating gate drive circuit 303.

By using a MESFET switch instead of a power MOSFET, the 3.0 to 4.2V voltage range of the lithium ion battery is more than adequate to fully enhance MESFET 304 into its low-resistance “on” state and avoids the need for over-sizing the power device to achieve acceptable conduction losses. The actual MESFET gate voltage must in fact be limited by gate buffer 303 to avoid excessive gate drive losses and potential device damage.

In contrast, a power MOSFET is generally not fully enhanced with only 3V on its gate, requiring an increase in device gate width and associated input capacitance.

Unlike using the prior art power MOSFET as a switch, MESFET 304 has no anti-parallel diode intrinsic to its device structure and cannot safely survive high voltages, even for short durations. The cathode of Zener diode 305 as shown is connected in parallel with MESFET 304 to protect the device from spurious voltage transients and noise. Zener 305 must be chosen to have a breakdown higher than a voltage Vbatt but lower than the avalanche breakdown of MESFET 304. Alternatively, Zener 305 may be connected in parallel to the series combination of MESFET 304 and MOSFET 311.

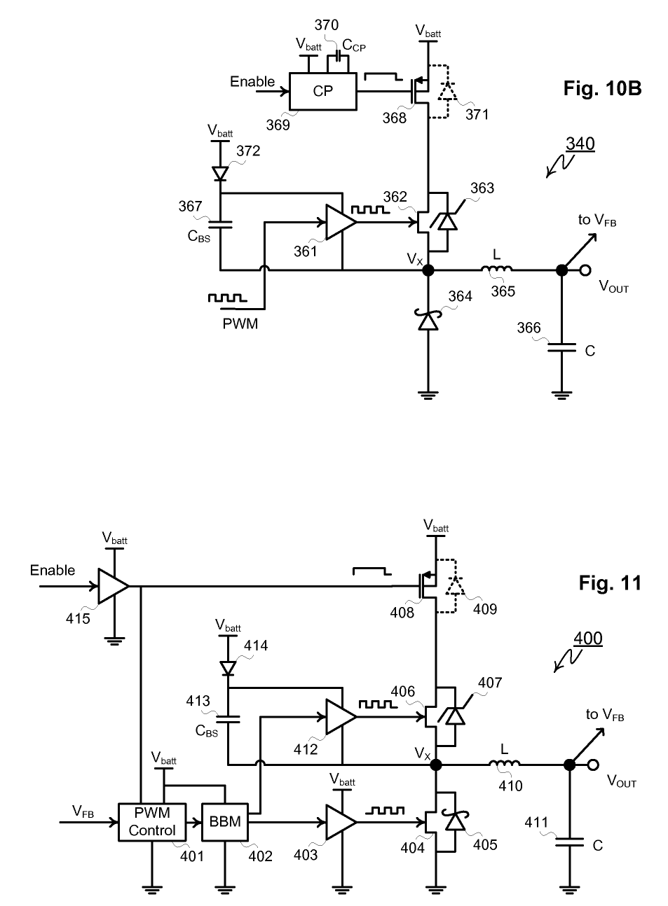

FIG. 10 illustrates alternative inventive implementations of cascode MESFET-MOSFET Buck converters. In circuit 340 of FIG. 10A, the series-connected MESFET and MOSFET have been reversed in their topological position (relative to the circuit 300 in FIG. 9) where MESFET 346 has its drain directly connected to Vbatt and its source connected to the source of P-channel MOSFET 342. The Buck converter further comprises Schottky rectifier 343, inductor 344 and filter capacitor 345.

Floating MESFET gate drive is accomplished using bootstrap circuit comprising gate buffer 347, bootstrap capacitor 349 and bootstrap diode 348 where the high frequency PWM input feeds gate buffer 346. MESFET 246 is driven by gate buffer 347 which limits the maximum gate voltage and current on the MESFET and optionally has its drain to source terminals protected by Zener diode 350. P-channel MOSFET 342 is driven by gate buffer 341b and switched at a very low rate on to enable and disable the converter. P-channel MOSFET 342 includes intrinsic anti-parallel diode 351 which remains reversed biased throughout circuit operation.

In circuit 360 of FIG. 10B, the series-connected P-channel MOSFET in the cascode switch of circuit 300 has been replaced with an N-channel MOSFET, where MESFET 362 has its drain connected to the source of N-channel MOSFET 368 which in turn has its drain connected to the converter's battery input. The Buck converter further comprises Schottky rectifier 364, inductor 365 and filter capacitor 366.

As previously described, floating MESFET gate drive is accomplished using bootstrap circuit comprising gate buffer 361, bootstrap capacitor 367 and bootstrap diode 372 where the high frequency PWM input feeds gate buffer 361. MESFET 362 is driven by gate buffer 361 which limits the maximum gate voltage and current on the MESFET and optionally has its drain to source terminals protected by Zener diode 363.

The enable switch comprises N-channel MOSFET 368 as driven by charge pump (CP) 369 and switched via its enable input at a very low rate to enable and disable the converter. Charge pump circuit 369 includes one or more capacitors such as 370 to step up the voltage to a sufficient voltage to adequately drive the N-channel MOSFET. The charge pump may operate at low currents with minimal impact on the converter's overall efficiency since fast turn-on speeds are not needed for N-channel MOSFET 368. N-channel MOSFET 368 includes intrinsic anti-parallel diode 371 which remains reversed biased throughout circuit operation.

### Cascode MESFET-MOSFET Synchronous Buck Converters

FIG. 11 illustrates an inventive synchronous Buck switching converter and voltage regulator using the aforementioned MESFET-MOSFET cascode switch, combined with a synchronous rectifier MESFET 404 and Schottky rectifier 405. In this circuit, MESFET 406 switched at a high frequency, controls the average current through inductor 410 and through feedback of the output voltage and pulse-width modulation controls the output voltage across filter capacitor 411. A synchronous rectifier comprising MESFET 404 in parallel with optional Schottky rectifier 405 recirculates inductor 410 current whenever MESFET switch 406. The Schottky rectifier action clamps the voltage to a few hundred millivolts below ground during the break-before make interval when both MESFETs 404 and 406 are off.

P-channel MOSFET 408, in series with MESFET 406, is enabled and conducting during converter operation and otherwise disabled during times when the converter is not operating. It is therefore switched at a much lower frequency than MESFET 406. While a second MOSFET can be inserted between MESFET 404 and ground, it is not necessary since MOSFET 408 cuts off any battery leakage currents when the converter is off.

As described in reference to FIG. 6A, the problem of MESFET 406 is that it may leak current in the off condition, thereby discharging the battery. To avoid this problem, converter 400 has added a P-channel MOSFET 408 to shut off the leakage. An inverter 415 drives the gate of MOSFET 408. Diode 409 is part of the transistor intrinsic to MOSFET 408. Since this device is not being switched at a high frequency, the MOSFET can be sized for low on-resistance and low power dissipation without adversely affecting switching losses.

As in the prior art circuit, the output of PWM control circuit 404 drives break-before-make (BBM) circuit 402. The output of BBM circuit has two outputs, one for floating gate-buffer 412 which in turn drives the input of N-channel MESFET 406, the other of which drives low-side gate buffer 403 connected to the gate of low-side synchronous rectifier MESFET 404. PWM circuit 302 and BBM circuit 402 are powered from the battery voltage. Gate drive buffers 403 and 412 are not simply CMOS inverters, but must limit the maximum gate voltage and current driving MESFETs 406 and 404. Unlike conventional MOSFETs, these power MESFETs have Schottky gate inputs. Failure to limit a MESFET's gate drive will increase drive losses, lower converter efficiency, and in the extreme may damage the device. MESFET gate drive methods are the subject of U.S. patent application “High Frequency Power MESFET Gate Drive Circuits” included herein by reference.

Floating gate driver 412 is powered by a boot strap circuit comprising bootstrap capacitor 413 and bootstrap diode 414. Bootstrap capacitor 413 charged to a voltage (Vbatt−V_{D}) whenever Vx is near ground, i.e. whenever floating MESFET 406 is not conducting (V_{D} is the forward voltage across diode 414 whenever capacitor 413 is being charged). Low-side gate buffer 403 is powered directly from the battery.

When MESFET 406 is conducting (provided MOSFET 408 is enabled) Vx rises to near Vbatt and the voltage potential of buffer 412 and bootstrap capacitor 413 rises to a voltage (relative to ground) above Vbatt, specifically (2·Vbatt−V_{D}). Since the source of MESFET 406 shares a common connection to gate buffer 412 and bootstrap capacitor 413, the entire gate buffer circuit “floats” with Vx. BBM circuit 402 includes a level-shifting function (not shown) to adjust the ground-referenced logic-level output of PWM circuit 401 to the input of floating gate drive circuit 412.

By using a MESFET switch instead of a power MOSFET, the 3.0 to 4.2V voltage range of the lithium ion battery is more than adequate to fully enhance a MESFET into its low-resistance “on” state and avoids the need for over-sizing the power device to achieve acceptable conduction losses. As described previously, MESFET gate voltages must in fact be limited by gate buffers 412 and 403 to avoid excessive gate drive losses and potential device damage. In contrast, a power MOSFET is generally not fully enhanced with only 3V on its gate, requiring an increase in device gate width and associated input capacitance.

Unlike using the prior art power MOSFET as a switch, MESFET 406 has no anti-parallel diode intrinsic to its device structure and cannot safely survive high voltages, even for short durations. The cathode of Zener diode 407 as shown is connected in parallel with MESFET 406 to protect the device from spurious voltage transients and noise. Zener 407 must be chosen to have a breakdown higher than a voltage Vbatt but lower than the avalanche breakdown of MESFET 406. Alternatively, Zener 407 may be connected in parallel to the series combination of MESFET 406 and MOSFET 418. Low-side synchronous rectifier MESFET 404 also has no intrinsic drain to so source diode, but may be paralleled with an external Schottky rectifier 405. Alternatively, the Schottky diode may be integrated into MESFET 404 as described in U.S. patent application “Power MESFET Rectifier” included herein by reference.

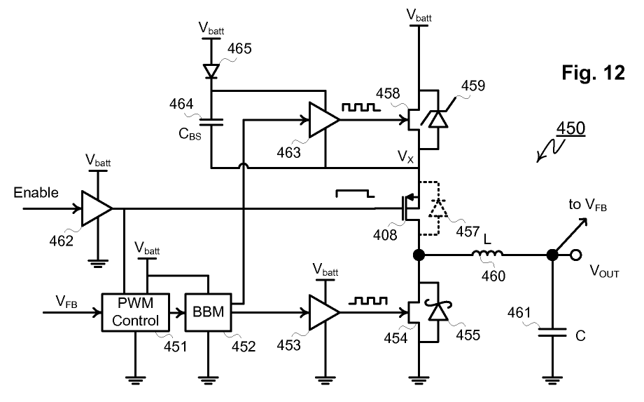

FIG. 12 illustrates alternative inventive implementation of a cascode MESFET-MOSFET synchronous Buck converter. In circuit 450, the series-connected MESFET and MOSFET have been reversed in their topological position (relative to the circuit 400 in FIG. 11) where MESFET 458 has its drain directly connected to Vbatt and its source connected to the source of P-channel MOSFET 456. The Buck converter further comprises synchronous rectifier MESFET 454, Schottky rectifier 456, inductor 344 and filter capacitor 461.

Floating MESFET gate drive is accomplished using bootstrap circuit comprising gate buffer 463, bootstrap capacitor 364 and bootstrap diode 465 where the high frequency output of PWM circuit 451 feeds both gate buffers 463 and 453 through break-before-make (BBM) circuit 452. MESFET 458 is driven by gate buffer 463 which limits the maximum gate voltage and current on the MESFET and optionally has its drain to source terminals protected by Zener diode 459. MESFET 454 is driven by gate buffer 453 which limits the maximum gate voltage and current on the MESFET and optionally has its drain to source terminals protected by Zener diode 456. P-channel MOSFET 456 is driven by gate buffer 462 and switched at a very low rate on to enable and to disable the converter. The enable input may also be used to further turn-on or disable PWM circuit 451 to save power, e.g. by stopping the oscillator internal to its circuitry. P-channel MOSFET 456 includes intrinsic anti-parallel diode 457 which remains reversed biased throughout circuit operation.

Additional variations on the switching regulators described above are possible. If every switching regulator is assumed to include a low-side switch and a high-side switch the following combinations are applicable for implementing a Buck converter:

(1) low-side switch: Schottky diode, high-side switch: N-channel MESFET.
(2) low-side switch: Schottky diode, high-side switch: MESFET cascode switch.
(3) low-side switch: N-channel MESFET, high-side switch: N-channel MESFET.
(4) low-side switch: N-channel MESFET, high-side switch: MESFET cascode switch.
(5) low-side switch: N-channel MESFET, high-side switch: MOSFET.
(6) low-side switch: MOSFET, high-side switch: N-channel MESFET.
(7) low-side switch: MOSFET, high-side switch: MESFET cascode switch.
(8) low-side switch: MESFET cascode switch, high-side switch: MOSFET.
(9) low-side switch: MESFET cascode switch, high-side switch: N-channel MESFET.
(10) low-side switch: MESFET cascode switch, high-side switch: MESFET cascode switch.
(11) Of these various Buck converter topologies, combination (5), (6), (7) and (8) are not suitable for operation at very high frequencies due to the speed and efficiency limitations imposed by the power MOSFET.

What is claimed is:

1. A cascode power switch comprising a MOSFET in series with a normally-off MESFET.

2. The cascode power switch of claim 1 where the MOSFET is N-channel.

3. The cascode power switch of claim 1 where the drain of the MOSFET connects to the source of the MESFET.

4. The cascode power switch of claim 1 where the source of the MOSFET connects to the drain of the MESFET.

5. The cascode power switch of claim 1 where the MOSFET is P-channel.

6. The cascode power switch of claim 5 where the drain of the MOSFET connects to the source of the MESFET.

7. The cascode switch of claim 5 where the source of the MOSFET connects to the drain of the MESFET.

8. The cascode switch of claim 1 where the MOSFET has a lower on-state resistance than the MESFET.

9. The cascode switch of claim 1 where the MESFET is used in circuitry where the MOSFET switches at a lower frequency from the MESFET.

10. The cascode switch of claim 1 where the MOSFET and MESFET gates are driven from different gate buffers.

11. The cascode switch of claim 1 where the MESFET is made of GaAs.

12. The cascode switch of claim 1 where the MESFET and the MOSFET are assembled in the same package.

13. A protected MESFET device comprising a normally-off MESFET in parallel with a Zener diode, the Zener diode having an avalanche voltage lower than the avalanche voltage of the MESFET.

14. A clamped cascode switch comprising a series connection of a normally off MESFET and a MOSFET, where the MESFET is connected in parallel with a Zener diode, where furthermore, the Zener diode has an avalanche voltage lower than the avalanche voltage of the MESFET.

15. The clamped cascode switch of claim 14 where the source of the MESFET is connected to the drain of the MOSFET.

16. The clamped cascode switch of claim 14 where the drain of the MESFET is connected to the source of the MOSFET.

17. The clamped cascode switch of claim 14 where the MOSFET is N-channel.

18. The clamped cascode switch of claim 14 where the MOSFET is P-channel.

19. The clamped cascode switch of claim 14 where the MESFET is made of GaAs.

20. A clamped cascode switch comprising a series connection of a normally off MESFET and a MOSFET, where the series connected MESFET and MOSFET is connected in parallel with a Zener diode, where furthermore, the Zener diode has an avalanche voltage lower than the avalanche voltage of the MESFET.

21. The clamped cascode switch of claim 20 where the source of the MESFET is connected to the drain of the MOSFET.

22. The clamped cascode switch of claim 20 where the drain of the MESFET is connected to the source of the MOSFET.

23. The clamped cascode switch of claim 20 where the MOSFET is N-channel.

24. The clamped cascode switch of claim 20 where the MOSFET is P-channel.

25. The clamped cascode switch of claim 20 where the MESFET is made of GaAs.

26. A cascode switch comprising a series connection of a normally off N-channel MESFET and an N-channel MOSFET, where the source of N-channel MOSFET is connected to the drain of the MESFET, and where the body of the N-channel MOSFET is connected to the source of the MESFET; and where the MOSFET includes a drain-to-body diode.

27. The cascode switch of claim 26 where the avalanche voltage of the drain-to-body diode of the MOSFET is lower than that of the avalanche voltage of the MESFET.

28. The cascode switch of claim 26 where a Zener diode is connected in parallel to the series combination of the MESFET and the MOSFET; having its cathode connected to the drain of the N-channel MOSFET and its anode connected to the source of the MESFET.

29. The cascode switch of claim 26 where the MESFET is made of GaAs.

30. A cascode switch comprising a series connection of a normally off N-channel MESFET and a P-channel MOSFET, where the source of P-channel MOSFET is connected to the drain of the MESFET, and where the body of the P-channel MOSFET is connected to the source of the MESFET; and where the MOSFET includes a drain-to-body diode.

31. The cascode switch of claim 30 where the avalanche voltage of the drain-to-body diode of the MOSFET is lower than that of the avalanche voltage of the MESFET.

32. The cascode switch of claim 30 where a Zener diode is connected in parallel to the series combination of the MESFET and the MOSFET; having its cathode connected to the source of the MESFET and its anode connected to the drain of the P-channel MOSFET.

32. The cascode switch of claim 30 where the MESFET is made of GaAs.
